(19) United States
(12) Patent Application Publication
(10) Pub. No.: US 2020/0176600 A1
(43) Pub. Date: Jun. 4, 2020

(54) HIGH-VOLTAGE SEMICONDUCTOR DEVICES AND METHODS FOR MANUFACTURING THE SAME

(71) Applicant: Vanguard International Semiconductor Corporation, Hsinchu (TW)

(72) Inventors: Chih-Wei LIN, Jhubei City (TW); Pi-Kuang CHUANG, Hsinchu City (TW)

(73) Assignee: Vanguard International Semiconductor Corporation, Hsinchu (TW)

(21) Appl. No.: 16/207,587

(22) Filed: Dec. 3, 2018

(51) Int. Cl. H01L 29/78; H01L 29/10; H01L 21/265; H01L 21/266; H01L 29/06; H01L 29/66

(52) U.S. Cl. CPC H01L 29/7833; H01L 29/1033; H01L 21/26513; H01L 21/2253; H01L 29/0619; H01L 29/66568; H01L 21/266

(57) ABSTRACT

A high-voltage semiconductor device is provided. The high-voltage semiconductor device includes a substrate. The high-voltage semiconductor device also includes a first well region, a second well region and a third well region which are disposed within the substrate. The first well region is separated from the second well region by the third well region. The first well region and the second well region have a second conductive type, and the third well region has the first conductive type. The high-voltage semiconductor device further includes a source region and a drain region which are respectively disposed in the first well region and the second well region. In addition, the high-voltage semiconductor device includes a gate structure disposed over the substrate. The high-voltage semiconductor device also includes a first doped region embedded in the third well region, wherein the first doped region has the second conductive type.

### BACKGROUND OF THE INVENTION

### Field of the Invention

The present invention relates to a high-voltage semiconductor device, and in particular to a high-voltage semiconductor device with a doped region for preventing the anti-body effect.

### Description of the Related Art

High-voltage semiconductor devices are applied in integrated circuits that have high-voltage and high power. Traditional high-voltage semiconductor devices, such as a vertically diffused metal oxide semiconductor (VDMOS) or a laterally diffused metal oxide semiconductor (LDMOS), are mainly used for devices that operated on 18 volts or higher. The advantages of high-voltage device technology include cost effectiveness and process compatibility, and this is why high-voltage device technology has been widely used in display driver IC devices, power supply devices, and such fields as power management, communications, automatics, and industrial control.

A gate voltage is used to generate the channel and control current between the source region and the drain region in the high-voltage semiconductor device. Traditional high-voltage semiconductor devices generally have an elongated channel length for restraining the punch-through effect, generated between the source region and the drain region, which can cause an increase in the area of the chip and the on-resistance of the transistor. Furthermore, since the mobility of a hole is less than that of an electron, the on-resistance of the p-type high-voltage semiconductor device is greater than that of the n-type high-voltage semiconductor device. Accordingly, it is difficult to improve upon the performance of a p-type high-voltage semiconductor device.

Therefore, it is necessary to develop a new high-voltage semiconductor device that can solve or improve the problems described above.

### BRIEF SUMMARY OF THE INVENTION

The disclosure provides a high-voltage semiconductor device. The high-voltage semiconductor device includes a substrate having a first conductive type. The high-voltage semiconductor device also includes a first well region, a second well region and a third well region which are disposed within the substrate. The first well region is separated from the second well region by the third well region. The first well region and the second well region have a second conductive type which is different than the first conductive type, and the third well region has the first conductive type. The high-voltage semiconductor device further includes a source region and a drain region which are respectively disposed in the first well region and the second well region. The source region and the drain region have the second conductive type. In addition, the high-voltage semiconductor device includes a gate structure disposed over the substrate and between the source region and the drain region. The high-voltage semiconductor device also includes a first doped region embedded in the third well region. The first doped region has the second conductive type.

The disclosure provides a high-voltage semiconductor device. The high-voltage semiconductor device includes a substrate having a first conductive type. The high-voltage semiconductor device also includes a first well region, a second well region and a third well region which are disposed within the substrate. The first well region is separated from the second well region by the third well region. The first well region and the second well region have a second conductive type which is different than the first conductive type, and the third well region has the first conductive type. The high-voltage semiconductor device further includes a source region and a drain region which are respectively disposed in the first well region and the second well region. The source region and the drain region have the second conductive type. In addition, the high-voltage semiconductor device includes a gate structure disposed over the substrate and between the source region and the drain region. The high-voltage semiconductor device also includes a first doped region embedded in the third well region. The first doped region and the first well region have a first distance therebetween. The first doped region and the second well region have a second distance therebetween. The first distance is substantially equivalent to the second distance.

The disclosure provides a method for manufacturing high-voltage semiconductor device. The method includes providing a substrate having a first conductive type. The method also includes forming a first well region and a second well region in the substrate. The first well region and the second well region have a second conductive type which is different than the first conductive type. The method further includes forming a third well region between the first well region and the second well region. The third well region has the first conductive type. In addition, the method includes performing an ion implantation process to form a first doped region in the substrate. The first doped region is embedded in the third well region, and the first doped region has the second conductive type. The method also includes forming a gate structure over the substrate to cover the first doped region. The method further includes forming a source region in the first well region and a drain region and in the second well region. The source region and the drain region have the second conductive type.

### BRIEF DESCRIPTION OF THE DRAWINGS

The present invention can be more fully understood by reading the subsequent detailed description and examples with references made to the accompanying drawings, wherein:

FIGS. 1A-1G are cross-sectional views of various stages of a process for forming a high-voltage semiconductor device in accordance with some embodiments of the present disclosure.

### DETAILED DESCRIPTION OF THE INVENTION

The high-voltage semiconductor device of the present disclosure is described in detail in the following description. In the following detailed description, for purposes of explanation, numerous specific details and embodiments are set forth in order to provide a thorough understanding of the present disclosure. The specific elements and configurations described in the following detailed description are set forth in order to clearly describe the present disclosure. It will be apparent, however, that the exemplary embodiments set forth herein are used merely for the purpose of illustration, and the inventive concept may be embodied in various forms without being limited to those exemplary embodiments. In addition, the drawings of different embodiments may use like and/or corresponding numerals to denote like and/or corresponding elements in order to clearly describe the present disclosure. However, the use of like and/or corresponding numerals in the drawings of different embodiments does not suggest any correlation between different embodiments. In addition, in this specification, expressions such as “first material layer disposed on/over a second material layer”, may indicate the direct contact of the first material layer and the second material layer, or it may indicate a non-contact state with one or more intermediate layers between the first material layer and the second material layer. In the above situation, the first material layer may not be in direct contact with the second material layer.

It should be noted that the elements or devices in the drawings of the present disclosure may be present in any form or configuration known to those skilled in the art. In addition, the expression “a layer overlying another layer”, “a layer is disposed above another layer”, “a layer is disposed on another layer” and “a layer is disposed over another layer” may indicate that the layer is in direct contact with the other layer, or that the layer is not in direct contact with the other layer, there being one or more intermediate layers disposed between the layer and the other layer.

In addition, in this specification, relative expressions are used. For example, “lower”, “bottom”, “higher” or “top” are used to describe the position of one element relative to another. It should be appreciated that if a device is flipped upside down, an element that is “lower” will become an element that is “higher”.

The terms “about” and “substantially” typically mean +/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. When there is no specific description, the stated value includes the meaning of “about” or “substantially”.

It should be understood that, although the terms first, second, third etc. may be used herein to describe various elements, components, regions, layers, portions and/or sections, these elements, components, regions, layers, portions and/or sections should not be limited by these terms. These terms are only used to distinguish one element, component, region, layer, portion or section from another region, layer or section. Thus, a first element, component, region, layer, portion or section discussed below could be termed a second element, component, region, layer, portion or section without departing from the teachings of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

This description of the exemplary embodiments is intended to be read in connection with the accompanying drawings, which are to be considered part of the entire written description. The drawings are not drawn to scale. In addition, structures and devices are shown schematically in order to simplify the drawing.

In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

The term “substrate” is meant to include devices formed within a transparent substrate and the layers overlying the transparent substrate. All transistor element needed may be already formed over the substrate. However, the substrate is represented with a flat surface in order to simplify the drawing. The term “substrate surface” is meant to include the uppermost exposed layers on a transparent substrate, such as an insulating layer and/or metallurgy lines.

According to embodiments of the present disclosure, a patterned mask layer is formed on a substrate before formation of a gate structure. The patterned mask layer has an opening to expose a channel region of a high-voltage semiconductor device. An anti-body effect doped region is formed by an ion implantation process. The anti-body effect doped region is located in or under the channel region, and between a source region and a drain region. As a result, the rise in threshold voltage (Vth) of the high-voltage semiconductor device is prevented, which improves the reliability and performance of the high-voltage semiconductor device.

It should also be noted that the present disclosure presents embodiments of a high-voltage semiconductor device, and may be included in an integrated circuit (IC) such as a microprocessor, memory device, and/or another IC. The IC may also include various passive and active microelectronic devices, such as thin film resistors, other capacitors (e.g. metal-insulator-metal capacitor, MIMCAP), inductors, diodes, metal-oxide-semiconductor field effect transistors (MOSFETs), complementary MOS (CMOS) transistors, bipolar junction transistors (BJTs), laterally diffused MOS (LDMOS) transistors, high power MOS transistors, or other types of transistors. One of ordinary skill may recognize other embodiments of semiconductor devices that may benefit from aspects of the present disclosure.

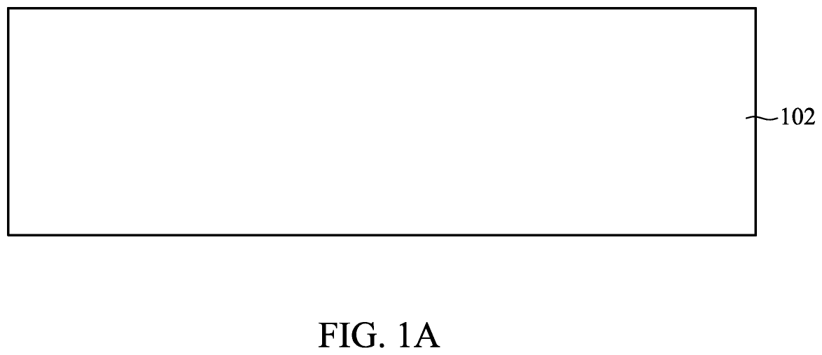

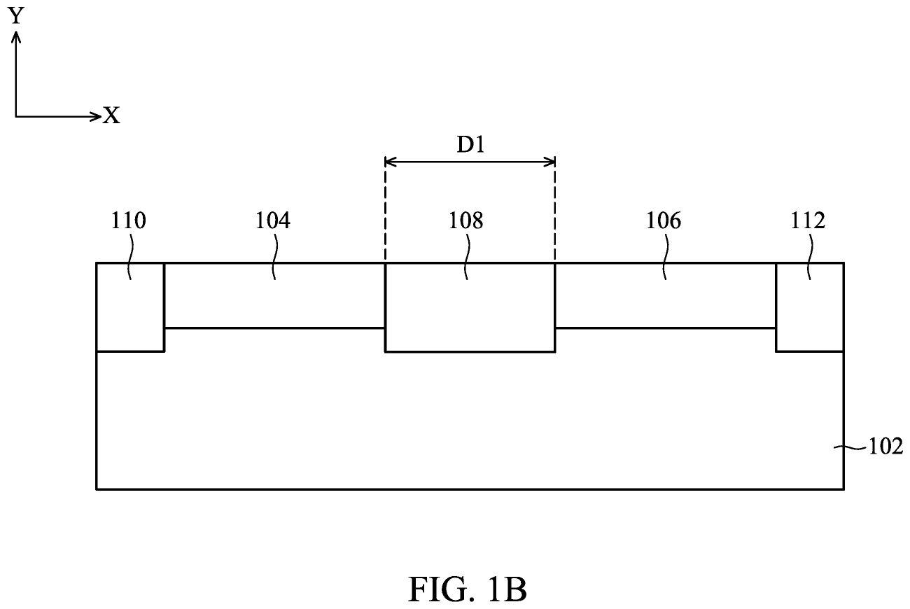

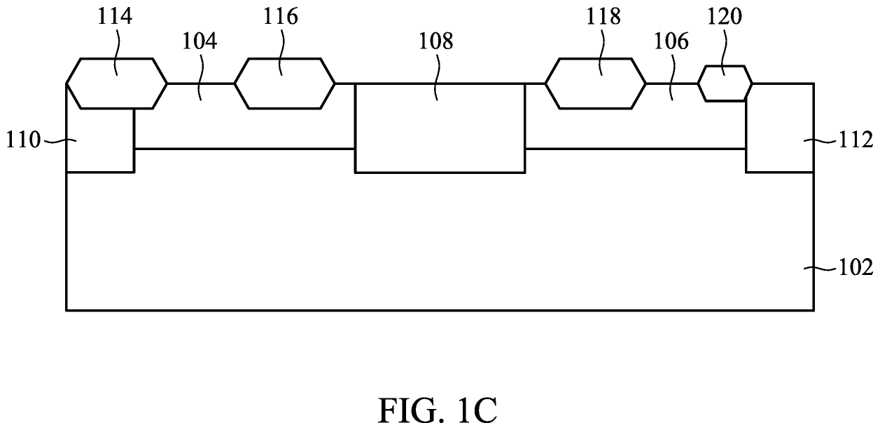

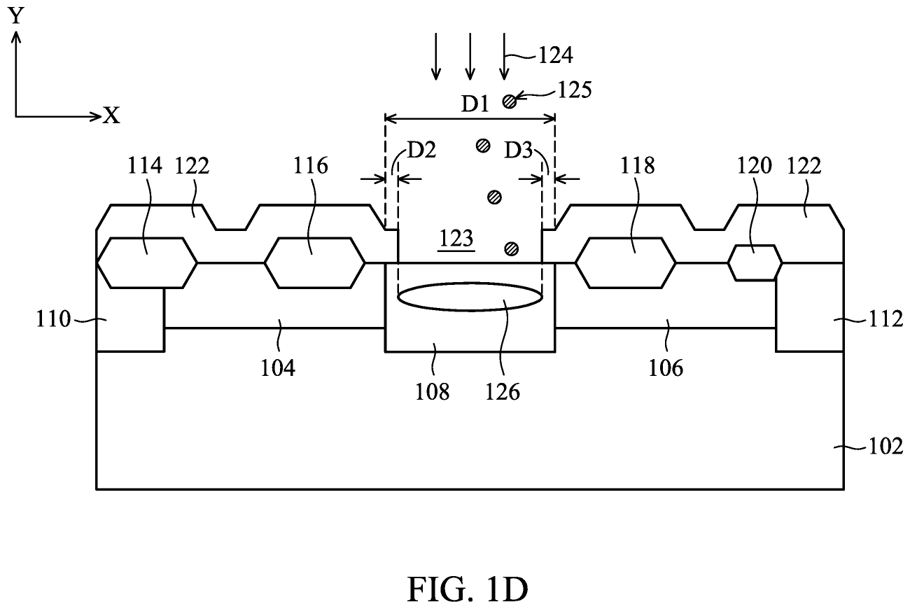

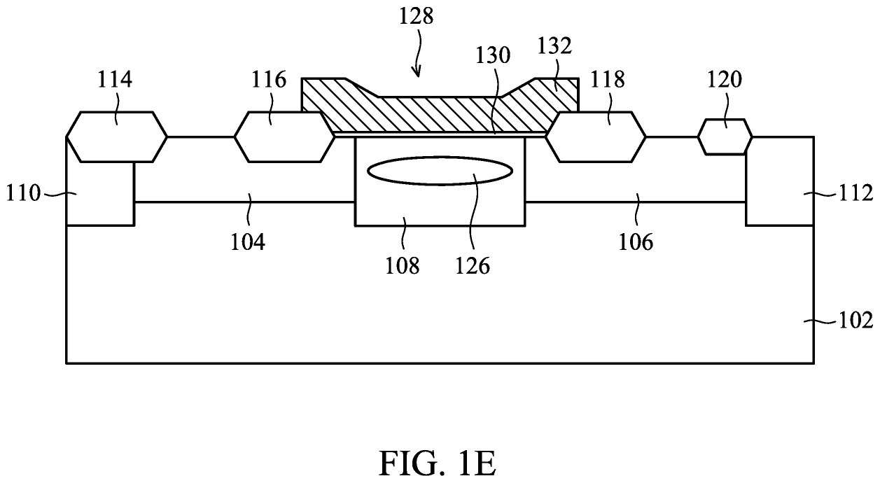

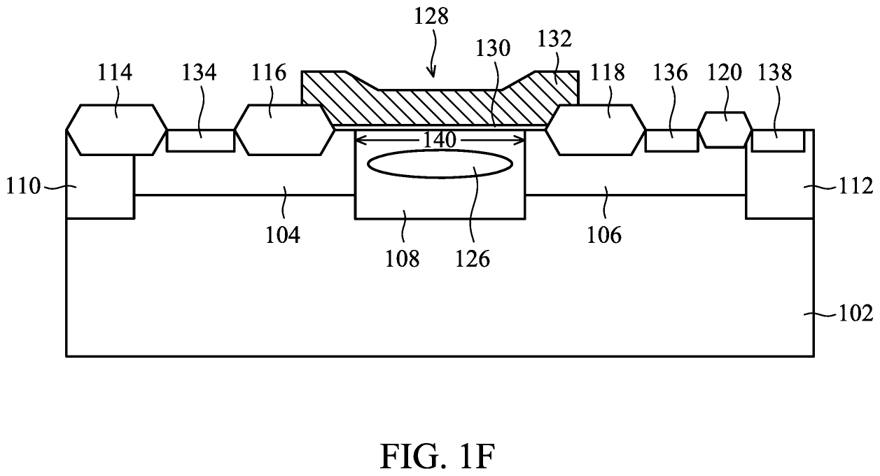

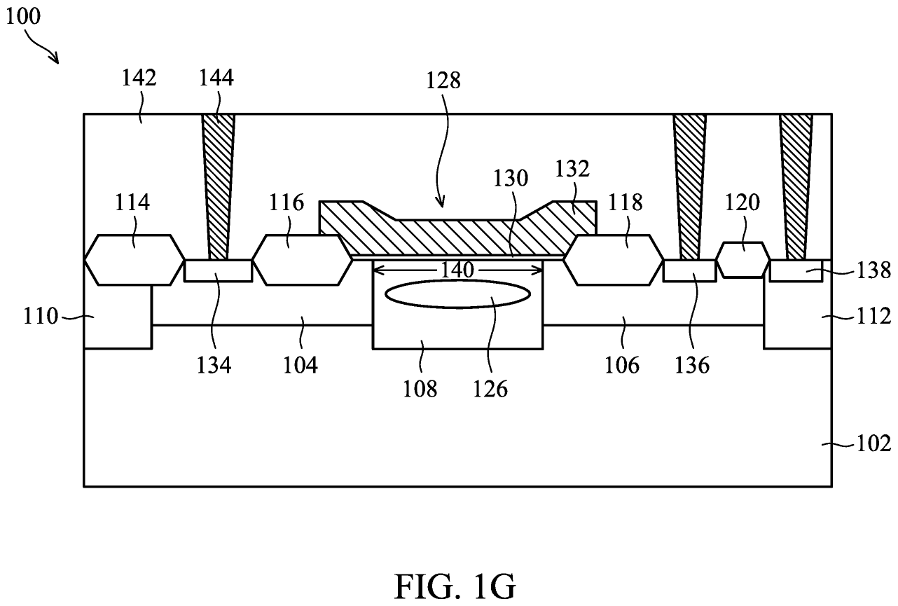

As shown in FIG. 1A, a substrate 102 is provided. The substrate 102 may be a semiconductor substrate, such as a bulk semiconductor, a semiconductor-on-insulator (SOI) substrate. The substrate 102 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 102 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In some embodiments, the substrate 102 has a first conductive type, such as p-type.

In addition, the substrate 102 includes an epitaxial layer (not shown) which is adjacent to the top surface of the substrate 102. The epitaxial layer may include, but is not limited to, Si, Ge, SiGe, III-V compound, or a combination thereof. The epitaxial layer may be formed by an epitaxial growth process, such as metal-organic chemical vapor deposition (MOCVD), metal-organic vapor phase epitaxy (MOVPE), plasma-enhanced chemical vapor deposition (PECVD), remote plasma-enhanced chemical vapor deposition (RP-CVD), molecular beam epitaxy (MBE), hydride vapor phase epitaxy (HVPE), liquid phase epitaxy (LPE), chloride vapor phase epitaxy (Cl-VPE), or any other suitable method. In some embodiments, the epitaxial layer has a first conductive type, such as p-type.

In some embodiments, as shown in FIG. 1B, well regions 104, 106, 108, 110 and 112 are formed in the substrate 102. In some embodiments, the well region 104 and the well region 106 have a second conductive type that is different from the first conductive type, such as n-type. The well regions 108, 110 and 112 have the first conductive type. In some embodiments, the well region 104 and the well region 106 can be regarded as high-voltage n-type well regions. The well regions 108, 110 and 112 can be regarded as high-voltage p-type well regions. In some embodiments, the doping concentration of the well region 104, 106, 108, 110 and 112 are in a range of about 10¹⁵ atoms/cm³ to about 10¹⁷ atoms/cm³. As shown in FIG. 1B, the well region 108 is located between the well region 104 and the well region 106. In some embodiments, the well region 104 and the well region 106 have a distance D1 therebetween along a first direction, such as X-axis. The distance D1 is in a range of about 2.0 μm to about 4.0 μm.

In some embodiments, as shown in FIG. 1C, isolation regions 114, 116, 118 and 120 are formed over the substrate 102. In some embodiments, the isolation regions 114, 116, 118 and 120 are field oxide regions that are formed by oxidation of silicon. As shown in FIG. 1C, the isolation region 114 covers a portion of the well regions 104 and 110. The isolation region 116 covers a portion of the well region 104. The isolation region 118 covers a portion of the well region 106. The isolation region 120 covers a portion of the well regions 106 and 112.

In some embodiments, as shown in FIG. 1D, a mask layer 122 is configured to cover the well regions 104, 106, 110 and 112 to expose the well regions 108. In some embodiments, the mask layer 122 covers a portion of the well region 108. As shown in FIG. 1D, the mask layer 122 has an opening 123 that exposes the portion of the well region 108. The mask layer 122 may be a photoresist layer or other suitable materials.

In some embodiments, as shown in FIG. 1D, a ion implantation process 124 is performed so that dopants 125 are implanted into the substrate 102. As a result, a doped region 126 is formed. In some embodiments, the doped region 126 is embedded in the well region 108, and separated from the well region 104 and the well region 106. In some embodiments, the doped region 126 and the well region 104 have a distance D2 therebetween along the first direction. In addition, the doped region 126 and the well region 106 have a distance D3 therebetween along the first direction. In some embodiments, the distance D2 and the distance D3 are in a range of about 0.2 μm to about 1.5 μm. In some embodiments, the distance D2 and the distance D3 are in a range of about 0.5 μm to about 1.0 μm. In some embodiments, the distance D2 is substantially equivalent to the distance D3. In some embodiments, the distance D2 is different from the distance D3.

In some embodiments, the dopant 125 used in the ion implantation process 124 includes group 15 elements (or referred as group VA elements), such as nitrogen (N), phosphorus (P), arsenic (As), antimony (Sb), and bismuth (Bi). In some embodiments, the phosphorus atoms or ions are implanted into the substrate 102 so that the doped region 126 with the second conductive type is formed. In some embodiments, the doping concentration of the doped region 126 is in a range of about 10¹⁶ atoms/cm³ to about 10¹⁷ atoms/cm³. In some embodiments, the doping concentration of the doped region 126 is in a range of about 5×10¹⁶ atoms/cm³ to about 10¹⁷ atoms/cm³. In some embodiments, the doping concentration of the doped region 126 is greater than that of the well region 104, 106, 108, 110 and 112. In some embodiments, during the performance of the ion implantation process 124, the dosage of the dopant 125 is in a range of about 10¹¹ atoms/cm² to about 10¹³ atoms/cm². In some embodiments, during the performance of the ion implantation process 124, the dosage of the dopant 125 is in a range of about 10¹² atoms/cm² to about 10¹³ atoms/cm².

In some embodiments, during the performance of the ion implantation process 124, the implanting energy is in a range of about 400 keV to about 600 keV. When the implanting energy is in the range aforementioned, the dopant 125 can be implanted to desired depth. In some embodiments, as shown in FIG. 1D, the bottom surface (or boundary) is located over the bottom surface (or boundary) of the well region 104 and the well region 106. Many variations and/or modifications can be made to embodiments of the disclosure. In some embodiments, a portion of the boundary of the doped region 126 is located over that of the well region 104 and the well region 106, and another portion of the boundary of the doped region 126 is located below that of the well region 104 and the well region 106.

After performing the ion implantation process 124, an anneal process may be performed. For example, the anneal process may be a spike annealing process which is performed at a temperature of from about 950° C. to about 1050° C., and for a time interval of from about 1 second to about 2 seconds.

The formation of the doped region 126 can restrain body effect. As a result, any rise in threshold voltage (Vth) of the high-voltage semiconductor device is prevented. The doped region 126 can also be referred as an anti-body effect doped region. In some cases, the doping concentration of the doped region 126 should be less than 10¹⁷ atoms/cm³. If the doping concentration of the doped region 126 is greater than 10¹⁷ atoms/cm³, it may lead to leakage of the high-voltage semiconductor device. In some cases, the doping concentration of the doped region 126 should be greater than 10¹⁶ atoms/cm³. If the doping concentration of the doped region 126 is less than 10¹⁶ atoms/cm³, it may not be enough to effectively restrain any rise in threshold voltage.

In some cases, the distance between the doped region 126 and the well region 104, or the distance between the doped region 126 and the well region 106 should be greater than 0.2 μm. Due to the same conductive type of the doped region 126 and the well region 104 (or the well region 106), the distance between the doped region 126 and the well region 104 (or the well region 106) with less than 0.2 μm may lead to leakage of the high-voltage semiconductor device. In some cases, the distance between the doped region 126 and the well region 104, or the distance between the doped region 126 and the well region 106 should be less than 1.5 μm, if the distance between the doped region 126 and the well region 104 (or the well region 106) is greater than 1.5 μm, it may not be enough to effectively restrain any rise in threshold voltage.

Next, as shown in FIG. 1E, the mask layer 122 is removed, and a gate structure 128 is formed over the substrate 102. As shown in FIG. 1E, the gate structure 128 includes a gate dielectric layer 130 and a gate electrode 132. The material of the gate dielectric layer 130 may include, but is not limited to, silicon oxide, silicon nitride, silicon oxynitride, high-k material, any other suitable dielectric material, or a combination thereof. The high-k material may include, but is not limited to, metal oxide, metal nitride, metal silicide, transition metal oxide, transition metal nitride, transition metal silicide, transition metal oxynitride, metal aluminate, zirconium silicate, zirconium aluminate. For example, the material of the high-k material may include, but is not limited to, LaO, AlO, ZrO, TiO, Ta₂O₅, Y₂O₃, SrTiO₃(STO), BaTiO₃(BTO), BaZrO, HfO₂, HfO₃, HfZrO, HfLaO, HfSiO, HfSiON, LaSiO, AlSiO, HfTaO, HfTiO, HfTaTiO, HfAlON, (Ba,Sr)TiO₃(BST), Al₂O₃, any other suitable high-k dielectric material, or a combination thereof. The gate dielectric layer 130 may be formed by chemical vapor deposition or spin-on coating. The chemical vapor deposition may include, but is not limited to, low pressure chemical vapor deposition (LPCVD), low temperature chemical vapor deposition (LTCVD), rapid thermal chemical vapor deposition (RTCVD), plasma enhanced chemical vapor deposition (PECVD), atomic layer deposition (ALD), or any other suitable method.

The material of the gate electrode 132 may include, but is not limited to, poly-silicon. The gate electrode 132 may be made of one or more metal, metal nitride, conductive metal oxide, or a combination thereof. The metal may include, but is not limited to, molybdenum, tungsten, titanium, tantalum, platinum, or hafnium. The metal nitride may include, but is not limited to, molybdenum nitride, tungsten nitride, titanium nitride or tantalum nitride. The conductive metal oxide may include, but is not limited to, ruthenium oxide or indium tin oxide. The gate electrode 132 may be formed by the previously described chemical vapor deposition (CVD), sputtering, resistive thermal evaporation, electron beam evaporation, or any other suitable methods.

In some embodiments, as shown in FIG. 1E, the gate dielectric layer 130 covers a portion of the well region 104 and the well region 106. In addition, the gate dielectric layer 130 extends across the well region 108. Namely, the gate dielectric layer 130 extends from over the well region 104 to over the well region 106. In some embodiments, as shown in FIG. 1E, the gate electrode 132 is formed over the gate dielectric layer 130, and extends from over the isolation region 116 to over the isolation region 118. Moreover, the doped region 126 is separated from the gate dielectric layer 130 of the gate structure 128.

Next, as shown in FIG. 1F, a source region 134, a drain region 136 and a body region 138 are formed in the substrate 102. The source region 134, the drain region 136 and the body region 138 are respectively formed in the well region 104, the well region 106 and the well region 112. As shown in FIG. 1F, the source region 134 is located between the isolation region 114 and the isolation region 116. The drain region 136 is located between the isolation region 118 and the isolation region 120. The body region 138 is separated from the drain region 136 through the isolation region 120.

In some embodiments, the source region 134 and the drain region 136 have the second conductive type, and have the doping concentration in a range of about 10¹⁹ atoms/cm³ to about substrate 102¹ atoms/cm³. The drain region 136 and the body region 138 may be formed by ion an implantation process or a diffusion process. Next, a rapid thermal annealing (RTA) process is performed to activate the dopants that have been implanted into the substrate 102.

In some embodiments, as shown in FIG. 1F, a channel region 140 is located between the well region 104 and the well region 106, and directly under the gate structure 128. In this embodiment, the doped region 126 may be located directly under or within the channel region 140.

Next, as shown in FIG. 1G, an inter-layer dielectric (ILD) 142 and a contact 144 are formed on the substrate 102 so that a high-voltage semiconductor device 100 is created. In some embodiments, the inter-layer dielectric 142 is a flowable film formed by a flowable CVD. In some embodiments, the inter-layer dielectric 142 is formed of a dielectric material such as Phospho-Silicate Glass (PSG), Boro-Silicate Glass (BSG), Boron-Doped Phospho-Silicate Glass (BPSG), undoped Silicate Glass (USG), or the like, and may be deposited by any suitable method, such as CVD, spin-on coating, plasma-enhanced CVD (PECVD), or a combination thereof.

The contact 144 may include a barrier layer and a conductive layer. The barrier layer may include titanium, titanium nitride, tantalum, tantalum nitride or the like. The material of the conductive layer may be copper, copper alloy, silver, gold, tungsten, aluminum, nickel, cobalt or the like.

In some embodiments, after the inter-layer dielectric 142 has been deposited to cover the substrate 102, the isolation regions 114, 116, 118, 120 and the gate structure 128, a plurality of openings are formed to penetrate the inter-layer dielectric 142 and expose a portion of top surfaces of the source region 134, the drain region 136 and the body region 138. The openings may be formed by suitable photolithography process and etching process. The photolithography process includes photoresist coating (e.g., spin-on coating), soft baking, mask alignment, exposure, post-exposure baking, developing the photoresist, rinsing and drying (e.g., hard baking). The photolithography process may also be implemented or replaced by another proper method such as maskless photolithography, electron-beam writing or ion-beam writing. The etching process may include dry etching, wet etching, and other etching methods.

After the openings exposing the source region 134, the drain region 136 and the body region 138 are formed, the materials of the barrier layer and the conductive layer are filled into the openings. As a result, the contacts 144 are formed. As shown in FIG. 1F, the contacts 144 are electrically connected to the source region 134, the drain region 136 and the body region 138, respectively.

In some embodiments, the high-voltage semiconductor device 100 is a symmetrical semiconductor device. As shown in FIG. 1G, the source region 134 and the drain region 136 are respectively formed in the well region 104 and the well region 106 that both have the second conductive type. Therefore, there is no additional drift region formed between the gate structure 128 and the drain region 136, and the size of the high-voltage semiconductor device 100 can be decreased. Accordingly, the density of the element per unit area of the high-voltage semiconductor device 100 increases.

In some embodiments, an anti-body effect doped region, which has the same conductive type as the source region and the drain region, is formed in the high-voltage well region under the gate structure. Accordingly, the rise in threshold voltage of the high-voltage semiconductor device is restrained. Therefore, the reliability and the performance of the high-voltage semiconductor device are improved.

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

1. A high-voltage semiconductor device, comprising:
a substrate having a first conductive type;
a first well region, a second well region and a third well region which are disposed in the substrate, wherein the first well region is separated from the second well region by the third well region, the first well region and the second well region have a second conductive type which is different than the first conductive type, and the third well region has the first conductive type;
a source region and a drain region which are respectively disposed in the first well region and the second well region, wherein the source region and the drain region have the second conductive type;
a gate structure disposed over the substrate and between the source region and the drain region; and
a first doped region embedded in the third well region, wherein the first doped region is directly under the gate structure, and the first doped region has the second conductive type.

2. The high-voltage semiconductor device as claimed in claim 1, wherein the first doped region is separated from the first well region and the second well region.

3. The high-voltage semiconductor device as claimed in claim 1, wherein the dopant of the first doped region includes nitrogen (N), phosphorus (P), arsenic (As), antimony (Sb), and bismuth (Bi).

4. The high-voltage semiconductor device as claimed in claim 1, wherein the dopant of the first doped region is phosphorus (P).

5. The high-voltage semiconductor device as claimed in claim 1, wherein the doping concentration of the first doped region is in a range between 10¹⁶ atoms/cm³ and 10¹⁷ atoms/cm³.

6. The high-voltage semiconductor device as claimed in claim 1, wherein the doping concentration of the first doped region is greater than the doping concentration of the first well region.

7. The high-voltage semiconductor device as claimed in claim 1, wherein the gate structure further comprises a gate dielectric layer which is disposed on the substrate, and extends from over the first well region to over the second well region.

8. The high-voltage semiconductor device as claimed in claim 7, wherein a portion of the third well region is disposed between the first doped region and the gate dielectric layer.

9. The high-voltage semiconductor device as claimed in claim 1, wherein a bottom boundary of the first doped region is higher than a bottom boundary of the first well region.

10. A high-voltage semiconductor device, comprising:
a substrate having a first conductive type;
a first well region, a second well region and a third well region which are disposed in the substrate, wherein the first well region is separated from the second well region by the third well region, the first well region and the second well region have a second conductive type which is different than the first conductive type, and the third well region has the first conductive type;
a source region and a drain region which are respectively disposed in the first well region and the second well region, wherein the source region and the drain region have the second conductive type;
a gate structure disposed over the substrate and between the source region and the drain region; and
a first doped region embedded in the third well region, wherein the first doped region is directly under the gate structure, the first doped region and the first well region have a first distance therebetween, the first doped region and the second well region have a second distance therebetween, and the first distance is substantially equivalent to the second distance.

11. The high-voltage semiconductor device as claimed in claim 10, wherein the first doped region has the second conductive type.

12. A method for manufacturing the high-voltage semiconductor device as set forth in claim 1, comprising:
providing a substrate having a first conductive type;
forming a first well region and a second well region in the substrate, wherein the first well region and the second well region have a second conductive type which is different from the first conductive type;
forming a third well region between the first well region and the second well region, wherein the third well region has the first conductive type;
performing an ion implantation process to form a first doped region in the substrate, wherein the first doped region is embedded in the third well region, and the first doped region has the second conductive type;
forming a gate structure over the substrate to cover the first doped region; and
forming a source region in the first well region and a drain region in the second well region, wherein the source region and the drain region have the second conductive type.

13. The method of manufacturing the high-voltage semiconductor device as claimed in claim 12, further comprising:
forming a mask layer to cover the first well region and the second well region to expose the third well region after the third well region is formed; and
implanting a first dopant into the third well region so that the first doped region is formed.

14. The method of manufacturing the high-voltage semiconductor device as claimed in claim 13, wherein the first dopant is phosphorus (P).

15. The method of manufacturing the high-voltage semiconductor device as claimed in claim 13, wherein the dosage of the first dopant is in a range of about 10¹² atoms/cm² to about 10¹³ atoms/cm².

16. The method of manufacturing the high-voltage semiconductor device as claimed in claim 13, wherein the mask layer covers a portion of the third well region.

17. The method of manufacturing the high-voltage semiconductor device as claimed in claim 12, wherein during the ion implantation process, the implantation energy is in a range of about 400 keV to about 600 keV.

18. The method of manufacturing the high-voltage semiconductor device as claimed in claim 12, wherein the doping concentration of the first doped region is greater than the doping concentration of the first well region.

19. The method of manufacturing the high-voltage semiconductor device as claimed in claim 12, wherein the first doped region is separated from the first well region and the second well region.

20. The method of manufacturing the high-voltage semiconductor device as claimed in claim 12, wherein the doping concentration of the first doped region is in a range of about 10¹⁶ atoms/cm³ to about 10¹⁷ atoms/cm³.
